(19) United States
(12) Patent Application Publication
(10) Pub. No.: US 2024/0363700 A1
(43) Pub. Date: Oct. 31, 2024

(54) SEMICONDUCTOR DEVICE HAVING A FIELD PLATE STRUCTURE

(71) Applicant: Infineon Technologies AG, Neubiberg (DE)

(72) Inventors: Lars Mueller-Meskamp, Dresden (DE); Ralf Rudolf, Dresden (DE); Anton Mauder, Kolbermoor (DE); Annett Winzer, Dresden (DE); Dirk Priefert, Moers (DE); Christian Schippel, Dresden (DE); Thomas Kuenzig, Baldham (DE)

(21) Appl. No.: 18/140,782

(22) Filed: Apr. 28, 2023

(51) Int. Cl. H01L 29/40; H01L 29/78

(52) U.S. Cl. CPC H01L 29/407; H01L 29/404; H01L 29/7816

(57) ABSTRACT

A semiconductor device includes: a silicon layer having an electrically insulated backside and a thickness in a range of 10 μm to 200 μm between a frontside of the silicon layer and the electrically insulated backside; a high voltage region and a low voltage region formed in the silicon layer and laterally spaced apart from one another; and a first field plate structure extending from the frontside into the silicon layer. The first field plate structure includes a field plate laterally separated from the silicon layer by a dielectric material and/or a pn junction.

### BACKGROUND

Ruggedness, low on resistance and high breakdown voltage are important parameters for integrated high voltage devices such as power diodes, LDMOS (laterally diffused metal-oxide semiconductor) transistors, etc. The electric potential and fields inside the device for all operation conditions must be adequately controlled to ensure satisfactory ruggedness, low on resistance and high breakdown voltage. Field curvature increases the electric field values which can lead to premature breakdown and/or avalanche conditions.

### SUMMARY

According to an embodiment of a semiconductor device, the semiconductor device comprises: a silicon layer having an electrically insulated backside and a thickness in a range of 10 μm to 200 μm between a frontside of the silicon layer and the electrically insulated backside; a high voltage region and a low voltage region formed in the silicon layer and laterally spaced apart from one another; and a first field plate structure extending from the frontside into the silicon layer, the first field plate structure comprising a field plate laterally separated from the silicon layer by a dielectric material and/or a pn junction.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of part of an SOI (silicon-on-insulator) device having a vertical field plate structure, according to an embodiment.

FIG. 2 illustrates a cross-sectional view of part of the SOI device with the field plate structure, according to another embodiment.

FIG. 3 illustrates a cross-sectional view of part of the SOI device with the field plate structure, according to another embodiment.

FIG. 4 illustrates a cross-sectional view of part of the SOI device with the field plate structure, according to another embodiment.

FIGS. 5A through 5E illustrate respective cross-sectional view of the field plate structure for different biasing embodiments.

FIGS. 6A through 6D illustrate respective plan views of different field plate structure configuration embodiments, for a radial diode configuration.

FIG. 7A illustrates a cross-sectional view taken along the line labelled A-A′ in any of FIGS. 6A through 6D.

FIG. 7B illustrates a distribution of equipotential lines in the part of the SOI layer shown in FIG. 7A under a biasing condition.

FIG. 7C illustrates the equipotential line distribution under the same biasing conditions as in FIG. 7B, but without the field plate structure included in the SOI diode device.

FIGS. 8 through 12 illustrate respective plan views of the frontside of the SOI layer and with the SOI device implemented as a power transistor, according to different embodiments.

FIGS. 13 through 17 illustrate the same power transistor device as in FIGS. 8 through 12, respectively, but with the field plate structures implemented in accordance with the mesa field plate embodiment illustrated in FIG. 3.

FIG. 18 illustrates a plan view of the frontside of the SOI layer and with the SOI device implemented as a radial power transistor, according to an embodiment.

FIG. 19 illustrates a corresponding cross-sectional view along the line labelled B-B′ in FIG. 18.

FIG. 20 illustrates a plan view of the frontside of the SOI layer and with the SOI device implemented as a radial power transistor, according to another embodiment.

FIG. 21 illustrates a corresponding cross-sectional view along the line labelled C-C′ in FIG. 20.

FIG. 22 illustrates a plan view of the frontside of the SOI layer and with the SOI device implemented as a radial power diode, according to an embodiment.

FIG. 23 illustrates a corresponding cross-sectional view along the line labelled D-D′ in FIG. 22.

### DETAILED DESCRIPTION

The embodiments described provide an SOI (silicon-on-insulator) device having a silicon layer with an electrically insulated backside. The electric field distribution within the SOI device is beneficially controlled using one or more deep trenches each with a conductive fill to direct an electric potential into the depth of the silicon layer, yielding a higher breakdown voltage, improved ruggedness, and lower on resistance. In some cases, the potential directed into the depth of the silicon layer may be used to generate an accumulation or inversion region and therefore guide current.

Described next, with reference to the figures, are embodiments of the SOI device.

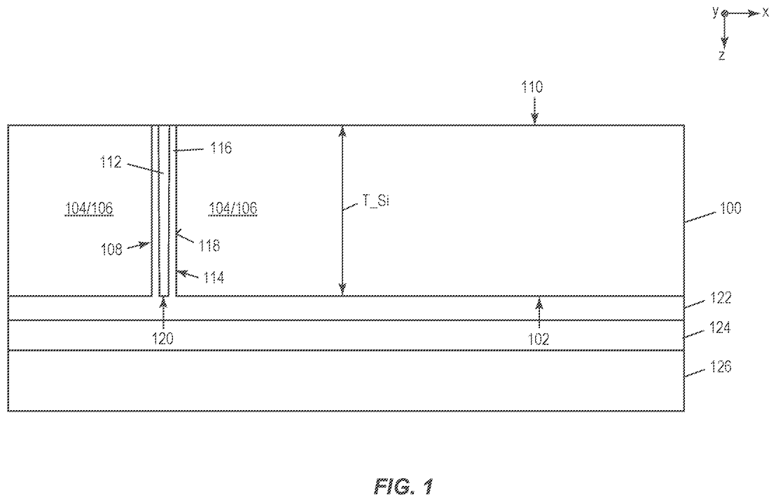

FIG. 1 illustrates a cross-sectional view of part of the SOI device, according to an embodiment. The SOI device includes a silicon layer 100 having an electrically insulated backside 102. A high voltage region 104 and a low voltage region 106 are formed in the silicon layer 100 and laterally spaced apart from one another. The high voltage region 104 may be a cathode region of a power diode and the low voltage region 106 may be an anode region of the power diode, for example. In another example, the high voltage region 104 may be a drain region of a power transistor such as an LDMOS transistor and the low voltage region 106 may be a source region of the power transistor. In another example, the high voltage region 104 may be part of a high voltage domain comprising one or more low voltage device structures within the high voltage domain and the low voltage region 106 may be part of a low voltage domain comprising one or more low voltage device structures within the low voltage domain. The respective low voltage device structures may extend only within the respective voltage domain. The respective low voltage device structures may have a breakdown voltage smaller than a nominal voltage between the low and high voltage domains, e.g., by a factor of at least 2 or at least 5 or at least 10. The respective low voltage device structures may comprise CMOS devices having a breakdown voltage less than 50V. In another example, the high voltage region 104 may be a high side region of a gate driver and the low voltage region 106 may be a low side region of a gate driver. These are just a few examples of the high and low voltage regions 104, 106 of the SOI and should not be considered limiting.

A field plate structure 108 extends from the frontside 110 of the silicon layer 100 into the silicon layer 100. The first field plate structure 108 includes a field plate 112 that can be used to direct an electric potential into the depth of the silicon layer 100. The field plate 112 is made of an electrically conductive material such as polysilicon and/or a metal or metal stack.

The field plate structure 108 may adjoin the high voltage region 104, adjoin the low voltage region 106, or laterally separate the high and low voltage regions 104, 106 from one another. The field plate 112 may be electrically connected to a same potential as the high voltage region 104, a same potential as the low voltage region 106, a different potential or signal, or may be floating.

In FIG. 1, the field plate structure 108 includes a trench 114 that extends from the frontside 110 into the silicon layer 100 and terminates at the electrically insulated backside 102. A dielectric material 116 lines each sidewall 118 of the trench 112. The dielectric material 116 may be SiOx, SiN, HfOx, etc. or a layer stack of two or more of these or similar dielectric materials. The field plate 112 terminates at the electrically insulated backside 102 at the bottom 120 of the trench 112 in FIG. 1, and is laterally separated from the silicon layer 100 by the dielectric material 116 that lines the sidewall(s) 118 of the trench 112.

In the case of a needle-shaped trench, the field plate trench 114 has a single curved sidewall 118 lined by the dielectric material 116. In the case of a stripe-shaped trench, the field plate trench 114 has two opposing sidewalls 118 lined by the dielectric material 116. The term ‘needle-shaped’ as used herein means a structure that is narrow and long in the depth-wise direction (z direction in FIG. 1) of the silicon layer 100. For example, the field plate trench 114 may resemble a needle, column, pillar, or spicule in the depth-wise direction of the silicon layer 100. The term ‘stripe-shaped’ as used herein means a structure having a longest linear dimension in a direction (y direction in FIG. 1) transverse to the depth-wise direction of the silicon layer 100. In either case, the field plate trench 114 may or may not extend to the backside 102 of the silicon layer 100.

A dielectric material 122 covers the backside 102 of the silicon layer 100, making the backside 102 electrically insulated. The dielectric material 122 covering the backside 102 of the silicon layer 100 may be an oxide having a thickness in a range of 0.8 μm (microns) to 35 μm, for example. At least one additional layer 124 may be formed on the dielectric material 122 covering the backside 102 of the silicon layer 100. For example, an adhesion promotion layer 124 may be formed on the backside dielectric material 122 and comprise any kind of material suitable for providing adhesion between a substrate 126 and the backside dielectric material 122, e.g., an organic adhesion promoter, any kind of glue, a DAF (die attach film) tape, or the like. One or more barrier layers 124 may be formed between the substrate 126 and the silicon layer 100 to increase the dielectric strength of the stack. For example, one or more metallization layers 124 such as Cu (copper), Al (aluminum), AlCu, etc., may be formed on the dielectric material 122 covering the backside 102 of the silicon layer 100. The substrate 126 such as a die carrier, lead frame, printed circuit board, etc. may be attached to the side of the metallization layer(s) 124 opposite the silicon layer 100.

In one embodiment, the thickness T_Si of the silicon layer 100 is in a range of 10 μm to 200 μm between the frontside 104 and the electrically insulated backside 102 of the silicon layer 100. The silicon layer 100 with the electrically insulated backside 102 may be realized by forming one or more devices such as a power diode, high voltage transistor, a gate driver for a power transistor, etc. in a bulk silicon wafer or in one or more epitaxial layers grown on a bulk silicon wafer, and then grinding the backside of the bulk silicon wafer to the final SOI thickness T_Si. For example, in FIG. 1, the backside wafer grinding may stop on the field electrode 112 in the field plate trench 114. In another example, the thinning may be continued, when reaching the field plate trench 114, to reach a predefined target thickness of the silicon layer 100. The thinned wafer backside is then covered by the dielectric material 122 to yield the electrically insulated backside 102 of the silicon layer 100. The resulting silicon layer 100 is thicker (e.g., T_Si=10 μm to 200 μm) than typical SOI device layers which usually have a thickness in the nanometer range.

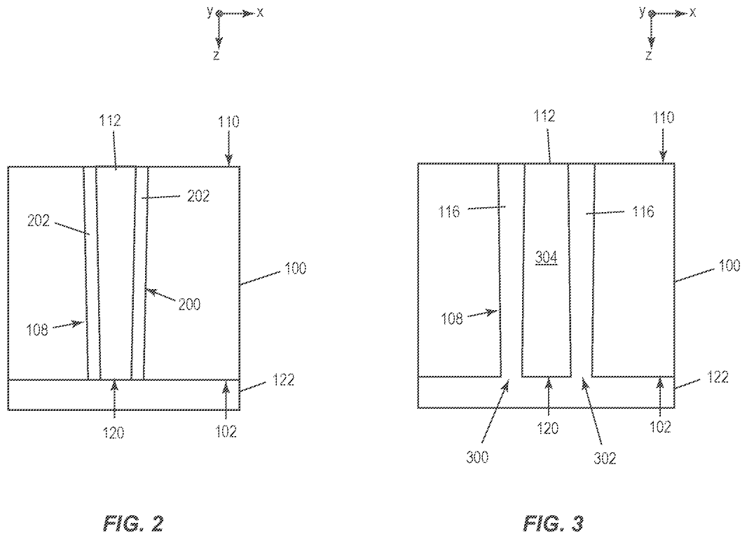

FIG. 2 illustrates a cross-sectional view of part of the SOI device with the field plate structure 108, according to another embodiment. In FIG. 2, the field plate 112 of the field plate structure 108 is laterally separated from the silicon layer 100 by a pn junction 200. The pn junction 200 is a boundary or interface between two types of semiconductor materials inside the silicon layer 100. For example, the silicon layer 100 may be p-type or n-type near the field plate structure 108 and an intervening region 202 of the opposite conductivity type may directly adjoin the field plate 112. The region 202 of the opposite conductivity type directly adjoining the field plate 112 may be formed by ion implantation or out-diffusion of n-type dopants in a p-type substrate or p-type dopants in an n-type substrate.

FIG. 3 illustrates a cross-sectional view of part of the SOI device with the field plate structure 108, according to another embodiment. In FIG. 3, the field plate structure 108 includes first and second trenches 300, 302 extending from the frontside 110 into the silicon layer 100 to delimit a semiconductor mesa 304. The first and second trenches 300, 302 are filled with the dielectric material 116. The semiconductor mesa 304 delimited by the first and second trenches 300, 302 is laterally isolated from the surrounding material of the silicon layer 100 by the dielectric material 116 and forms the field plate 112 of the field plate structure 108 in this embodiment. The semiconductor mesa 304 behaves as a conductive plug with an isolated sidewall implemented by the dielectric material 116. The lateral isolation instead may be realized by a pn junction, e.g., as described above in connection with FIG. 2, or by both the dielectric material 116 and a pn junction.

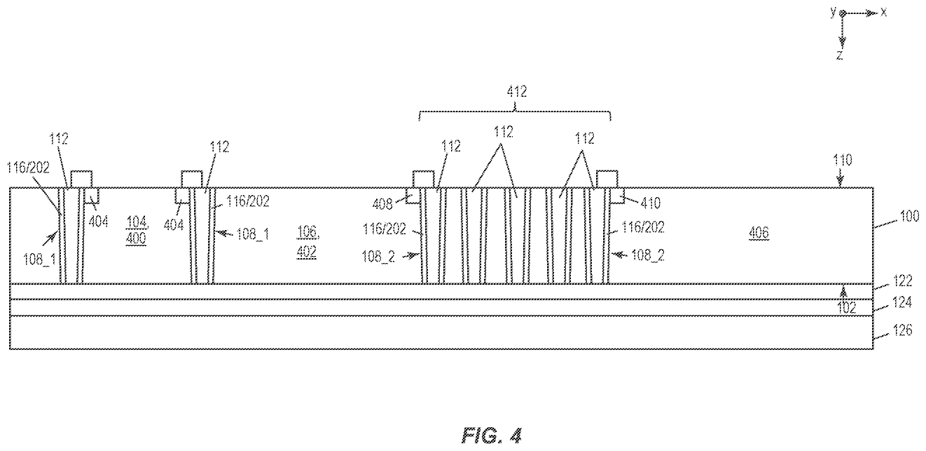

FIG. 4 illustrates a cross-sectional view of part of the SOI device with the field plate structure 108, according to another embodiment. In FIG. 4, a first field plate structure 108_1 electrically isolates first and second circuit areas 400, 402 from one another within the silicon layer 100. The first circuit area 400 may correspond to the high voltage region 104 and the second circuit area 402 may correspond to the low voltage region 106 in FIG. 1 or vice-versa, for example. The field plate 112 of the first field plate structure 108_1 may be electrically connected to a doped region 404 of the first circuit area 400 and/or the second circuit area 402. The doped region 404 may be of the same or different conductivity type as the surrounding material of the silicon layer 100 but with a higher doping concentration than a background doping concentration of the silicon layer 100. For example, the doped region 404 may be a p+ or an n+ doped region in the respective circuit area 400, 402.

An electric potential in one of the circuit areas 400, 402 such as substrate/ground, high potential, or any other potential may be coupled to the adjacent trench field plate 112 to shield the respective device from the other circuit area 400, 402. Alternatively, any potential or signal present on any part of the chip (die) may be routed to the trench field plate 112 to improve shielding. Alternatively or additionally, the potential of the field plate(s) 112 may be used to engineer the field distribution within the circuit area 400.

In FIG. 4, the SOI device also includes at least one second field plate structure 108_2 extending into the silicon layer 100 from the frontside 110. Each second field plate structure 108_2 includes a field plate 112 laterally separated from the silicon layer 100 by a dielectric material 116 and/or a pn junction formed with an intervening region 202 of the opposite conductivity type. The second field plate structure(s) 108_2 electrically isolate the second circuit area 402 from a third circuit area 406 which may be a high voltage region, low voltage region, or an intermediate voltage region. The field plate 112 of one second field plate structure 108_2 may be electrically connected to a doped region 408 of the second circuit area 402. The field plate 112 of another second field plate structure 1082 may be electrically connected to a doped region 410 of the third circuit area 406. The doped regions 408, 410 may be of the same or different conductivity type as the surrounding material of the silicon layer 100 but with a higher average doping concentration. For example, the doped regions 408, 410 may be p+ or n+ doped regions in the respective circuit areas 402, 406.

The multi-trench arrangement 412 used to provide isolation between the second and third circuit areas 402, 406 in FIG. 4 may be used to couple any electric potential to any trench field plate 112, e.g., to route low and/or high circuit potentials to the adjacent field plate structure 108. Such biased vertical field plates 112 may effectively screen parts of the die from each other and reduce crosstalk.

As shown in FIG. 4, the first field plate structure 1081 may adjoin the high voltage region 104 and the field plate 112 of the first field plate structure 108_1 may be electrically connected to a same potential as the high voltage region 104, e.g., by a corresponding highly doped region 404. One of the second field plate structures 1082 may adjoin the low voltage region 106 and the field plate 112 of the second field plate structure 1082 may be electrically connected to a same potential as the low voltage region 106, e.g., by a corresponding highly doped region 408.

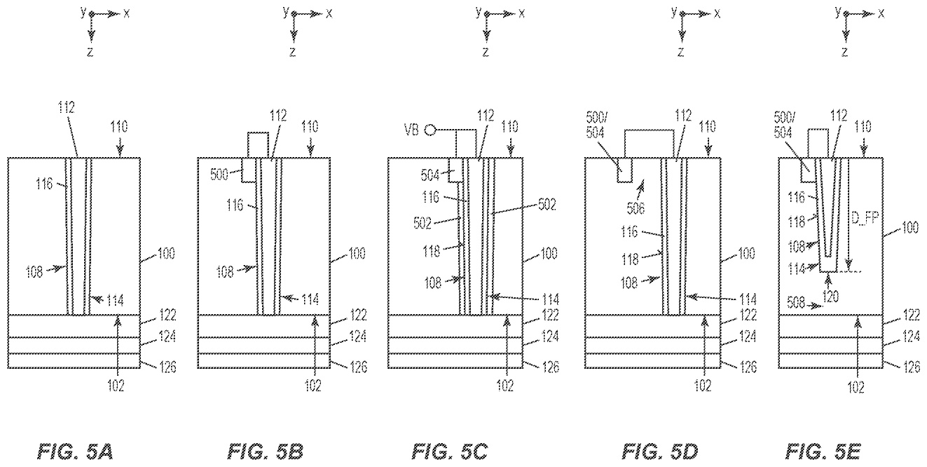

FIGS. 5A through 5E illustrate respective cross-sectional view of the field plate structure 108 for different biasing embodiments.

In FIG. 5A, the field plate 112 of the field plate structure 108 is electrically floating. That is, the field plate 112 is not connected to a defined electric potential but instead floats to an intermediate potential derived from all adjacent potentials. The field plate potential in FIG. 5A may differ from left-to-right and/or from top-to-bottom.

In FIG. 5B, the field plate 112 of the field plate structure 108 is electrically connected to a doped region 500 of the same conductivity type as the surrounding material of the silicon layer 100 but with a higher doping concentration than a background doping concentration of the silicon layer 100. For example, the doped region 500 may be a p+ doped region if the surrounding material of the silicon layer 100 is p-type or an n+ doped region if the surrounding material of the silicon layer 100 is n-type. For example, the doped region 500 may adjoin the field plate structure 108, e.g., the doped region 500 may be in direct contact to a sidewall 118 of the field plate structure 108 and/or the dielectric material 116. More generally, the potential of the field plate 112 may be fixed to any available potential. In FIG. 5B, the field plate 112 is biased to an adjacent surface potential and pulls all adjacent potentials (top/bottom/left/right) towards the applied potential and thus changes the field distribution in the x, y and z directions.

In FIG. 5C, the field plate 112 of the field plate structure 108 is electrically connected to an electric potential of a bias voltage VB such that a depletion region, accumulation region, or conductive channel 502 forms along a sidewall 118 of the field plate structure 108 when the electric potential is applied. The bias voltage VB may be applied to a highly doped region 504 of the opposite conductivity type as the surrounding material of the silicon layer 100. For example, the highly doped region 504 may be an n+ region if the surrounding material of the silicon layer 100 is p-type or a p+ region if the surrounding material of the silicon layer 100 is n-type.

The configuration of the field plate structure 108 in FIG. 5D is similar to the configuration in FIG. 5B or 5C, but with the doped region 500/504 to which the field plate 112 is electrically connected being laterally spaced apart from the adjacent sidewall 118 of the field plate trench 114 by a lower doped region 506 of the silicon layer 100. The lower doped region 506 may have the same background dopant concentration as the surrounding material of the silicon layer 100.

The configuration of the field plate structure 108 in FIG. 5E is similar to the configuration in FIG. 5B or 5C, but with the field plate structure 108 terminating at a depth D_FP in the silicon layer 100 before reaching the electrically insulated backside 102. The bottom 120 of the field plate trench 112 may be vertically separated from the dielectric material 122 that covers the backside 102 of the silicon layer 100 by a region 508 of the silicon layer 100. The dielectric material 116 that separates the field plate 112 from the surrounding material of the silicon layer 100 may line each sidewall 118 and the bottom 120 of the field plate trench 114. Separately or in combination, the field plate trench 114 may be needle-shaped and the field plate 112 may be tapered, e.g., as shown in FIG. 5E where the lateral width (linear dimension in the x direction in FIG. 5E) decreasing in the vertical direction (z direction in FIG. 5E) heading from the frontside 110 to the electrically insulated backside 102 of the silicon layer 100.

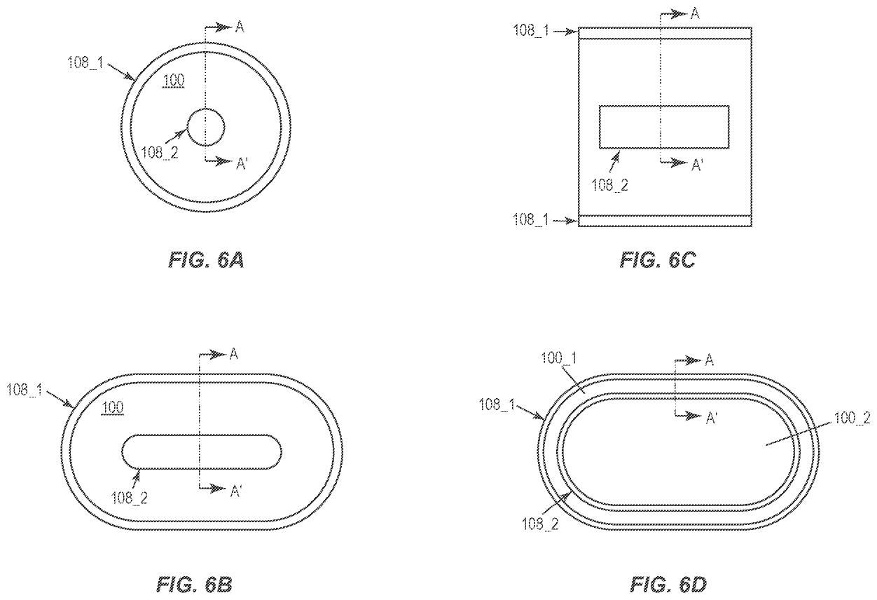

FIGS. 6A through 6D illustrate respective plan views of different field plate structure configuration embodiments, for a radial diode configuration.

In FIG. 6A, a first field plate structure 108_1 encircles at least part of the silicon layer 100 and a second field plate structure 108_2 is spaced inward from the first field plate structure 108_1. The field plate structures 108_1, 108_2 have a circular profile in FIG. 6A.

In FIG. 6B, a first field plate structure 108_1 encircles at least part of the silicon layer 100 and a second field plate structure 108_2 is spaced inward from the first field plate structure 108_1. The field plate structures 108_1, 108_2 have an oval profile in FIG. 6B.

In FIG. 6C, a first field plate structure 108_1 delimits at least part of the silicon layer 100 and a second field plate structure 108_2 is spaced inward from the first field plate structure 108_1. The field plate structures 108_1, 108_2 have a rectilinear profile in FIG. 6B.

In FIG. 6D, a first field plate structure 108_1 encircles a first part 100_1 of the silicon layer 100 and a second field plate structure 108_2 encircles a second part 100_2 of the silicon layer 100 laterally spaced inward from the first part 100_1. The field plate structures 108_1, 108_2 have an oval profile in FIG. 6D but may have a circular or other type of profile that encircles the first part 100_1 and the second part 1002, respectively, of the silicon layer 100.

Each field plate structure 108_1, 108_2 is each shown as a contiguous structure in FIGS. 6A through 6D. Alternatively, one or both of field plate structures 108_1, 1082 may be segmented into a plurality of trench sections, e.g., in the form of pillars, columns, rectilinear segments, etc. that are laterally spaced apart from one another by a region of the silicon layer 100.

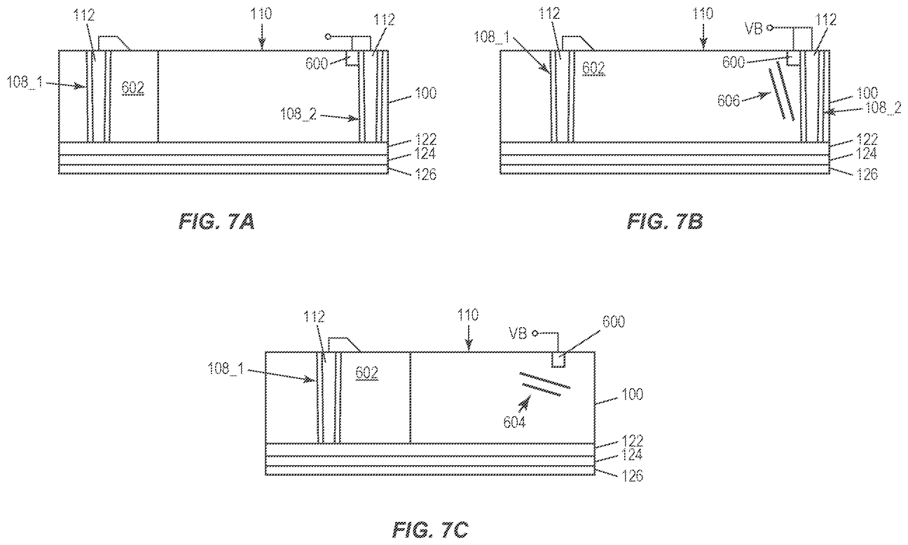

FIG. 7A illustrates a cross-sectional view taken along the line labelled A-A′ in any of FIGS. 6A through 6D. FIG. 7B illustrates a distribution of equipotential lines in the part of the silicon layer 100 shown in FIG. 7A, when a positive electric potential of a bias voltage VB is applied to the cathode region 600 of the diode and a lower potential or ground is applied to the anode region 602 of the diode. The field plate 112 of the inner (second) field plate structure 108_2 is electrically connected to the cathode region 600 of the diode and the field plate 112 of the outer (first) field plate structure 108_1 is electrically connected to the anode region 602 of the diode. FIG. 7C illustrates the equipotential line distribution under the same biasing conditions as in FIG. 7B, but without the inner (second) field plate structure 108_2 included in the SOI diode device.

As shown in FIG. 7C, the electric field lines have some curvature around the cathode region 600 of the diode absent the inner (second) field plate structure 108_2 as indicated by the mostly horizontal equipotential lines 604, since the field lines are dominated by the vertical field between the positive (high) electric potential of the bias voltage VB and the backside (low) potential of the bias voltage VB. As shown in FIG. 7B, the field line curvature is instead directed into the dielectric material 116 of the inner (second) field plate structure 108_2 as indicated by the mostly vertical equipotential lines 606, since the field plate 112 of the inner (second) field plate structure 108_2 directs the positive electric potential of the bias voltage VB deeper into the silicon layer 100. The dielectric material 116 of the inner (second) field plate structure 108_2 can handle significantly higher field peaks (e.g., 20 to 50× higher capability) compared to the cathode region 600 of the diode, yielding a more efficient device.

FIGS. 8 through 12 illustrate respective plan views of the frontside 110 of the silicon layer 100 and with the SOI device implemented as a power transistor, according to different embodiments. The power transistor may be a FET (field-effect transistor) or a JFET (junction FET), for example. The power transistor is illustrated as an LDMOS power transistor in FIGS. 8 through 12, with the high voltage region 104 of the SOI device being a drain region of the LDMOS power transistor and the low voltage region 106 of the SOI device being a source region of the LDMOS power transistor. At least one of the field plates 108, first field plate structures 108_1, and/or second field plate structures 108_2 shown in FIGS. 8 through 12 may be used as a vertical gate or side gate for the respective transistor.

In FIG. 8, the field plate structure 108 laterally surrounds a device cell that includes the source region 106, the drain region 104, and a body region 700 which is interposed between the source region 106 and the drain region 104 of the power transistor and of the opposite conductivity type as the source and drain regions 106, 104. The field plate structure 108 extends at least partly along the body region 700. The field plate 112 included in the field plate structure 108 is biased such that an inversion region, accumulation region, or depletion region (side gate) 702 formed along a sidewall of the field plate structure 108 defines a side gate at least partly along the body region 700.

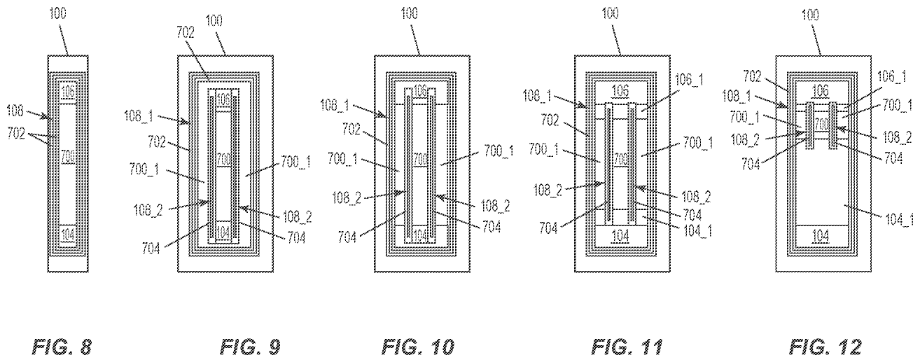

In FIG. 9, a first (outer) field plate structure 108_1 laterally surrounds the device cell that includes the source region 106, the drain region 104, and the body region 700 of the power transistor. A second (inner) field plate structure 108_2 extends from the frontside 110 of the silicon layer 100 into the body region 700. The second field plate structure 108_2 is spaced inward from the first field plate structure 108_1 such that a segment 700_1 of the body region 700 is interposed between the first field plate structure 108_1 and the second field plate structure 108_2. The field plate 112 of the second field plate structure 108_2 is biased such that an inversion region, accumulation region, or depletion region (side gate) 704 formed along a sidewall of the second field plate structure 108_2 defines a side gate along a side of the body region segment 700_1 opposite the first field plate structure 108_1.

In FIG. 10, the second field plate structure 108_2 extends into the source region 106 of the power transistor at one end and into the drain region 104 of the power transistor at the opposite end.

FIG. 11 is similar to FIG. 10, but the source region 106 has a source region extension 106_1 and the drain region 104 has a drain region extension 104_1. The second field plate structure 108_2 extends into both the source region extension 106_1 and the drain region extension 104_1 of the power transistor.

FIG. 12 is similar to FIG. 11, but the drain region extension 104_1 is significantly longer than the source region extension 106_1. The second field plate structure 108_2 extends into source-side part of the drain region extension 104_1 of the power transistor but terminates before reaching near the drain region 104.

In each of FIGS. 8 through 12, the field electrode 112 or mesa 304 of the field plate structures 108_1, 108_2 may be isolated by a dielectric trench liner 116 or a pn junction 200 and may be used as a side gate to the active device region, forming a conductive region (channel) by inversion, accumulation or depletion 702, 704 at the field plate structure sidewall. For narrow devices, the side gate 702, 704 may affect the whole width of the body region 700 in accumulation or depletion. The side gate 702, 704 may extend along the complete device length (FIGS. 8 through 11) or just along part of the device length (FIG. 12). Accordingly, the ‘gated’ part of the power transistor may likewise extend along the complete device length or along just part of the device length.

The power transistor may have one or more side gates 702, 704 for gating one or more conductive channels along the corresponding field plate structure 108_1, 108_2 or in the semiconductor volume, with ‘gates’ on both sides of the body region 700 being even more beneficial. A multitude of gated channels may be formed in parallel by a corresponding number of field plate structures 108 in the body region 700. The field plate structure 108_1 that surrounds the active device may act as an isolation/field plate only or may have a double function for isolation and gating (FIG. 8, optionally in FIGS. 10 through 12). Trench-based side gates may be combined with any kind of top or back gate to act together on the active silicon volume.

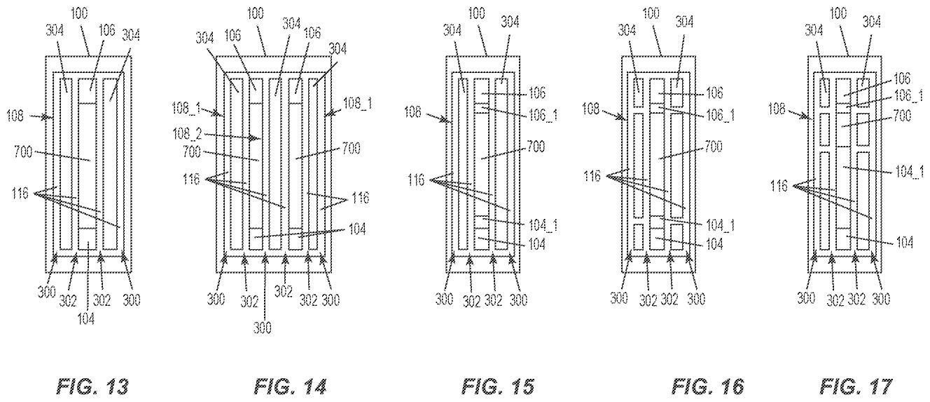

FIGS. 13 through 17 illustrate the same power transistor device as in FIGS. 8 through 12, respectively, but with the field plate structures 108_1, 108_2 implemented in accordance with the mesa field plate embodiment illustrated in FIG. 3. Accordingly, each field plate structure 108_1, 108_2 includes first and second trenches 300, 302 each extending from the frontside 110 into the silicon layer 100 and delimiting a semiconductor mesa 304. The first and second trenches 300, 302 of each field plate structure 108_1, 108_2 are filled with a dielectric material 116 that laterally isolates the adjoining semiconductor mesa 304 from the remainder of the silicon layer 100. According to this embodiment, the semiconductor mesa 304 of each field plate structure 108_1, 108_2 may be used as a side gate 702, 704 as described above in connection with FIGS. 8 through 12.

It should be considered that the features of the embodiments of FIGS. 8 through 12 apply analogously for NMOS and PMOS devices.

Any side gate effect may cause depletion, accumulation or even a channel along the sidewall of each field plate structure 108_1, 108_2 and therefore directly modulate the conductivity adjacent to the field plate structure 108_1, 108_2 or may pinch or open a potential barrier in a narrow slice/ridge/mesa, modulated by the adjacent field plate structure trenches 300, 302. Any side gate effect may be combined with device functions such as gates and doped regions from front or backside, e.g., having an LDMOS on top, with a directly gated channel and a source and/or drain extension 106_1, 104_1 and body region 700 that is modulated by a suitable potential applied to the semiconductor mesas 304 delimited by the field plate structure trenches 300, 302.

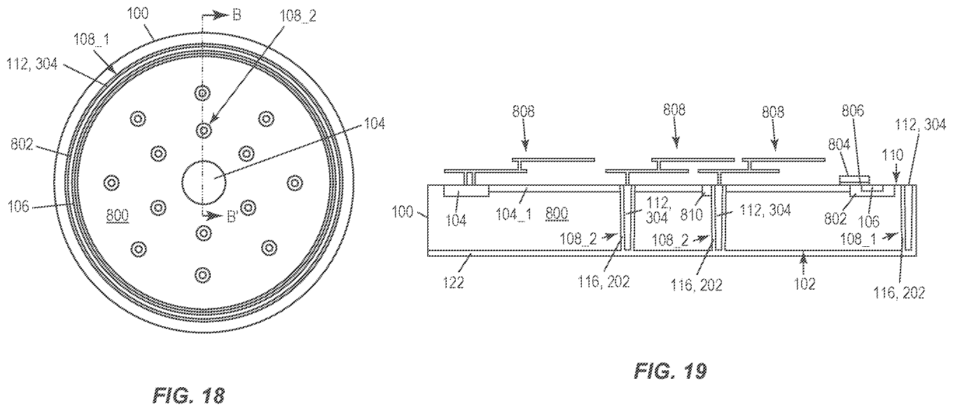

FIG. 18 illustrates a plan view of the frontside 110 of the silicon layer 100 and with the SOI device implemented as a radial power transistor, according to an embodiment. FIG. 19 illustrates a corresponding cross-sectional view along the line labelled B-B′ in FIG. 18.

In FIGS. 18 and 19, the high voltage region 104 is a drain region of the radial power transistor, the low voltage region 106 is the source region of the radial power transistor, and the drain region 104 is at the center of the radial power transistor. A bulk region 800 of the radial power transistor connects a body region 802 of the transistor to the drain region 104. An extension region 104_1 adjoining the drain region 104 may extend into the bulk region 800 in a direction of the body region 802. The extension region 104_1 has the same conductivity type as the drain region 104 but is less heavily doped. The extension region 104_1 may be configured to take the voltage between the high voltage region 104 and the low voltage region 106 in a blocking state of the transistor (at diode as describer later) and which is also referred to herein as ‘drift region’.

The radial power transistor is illustrated as a planar gate device in FIG. 19, with a gate electrode 804 formed above the frontside 110 of the silicon layer 100 and a gate dielectric 806 separating the gate electrode 804 from the silicon layer 100. The gate structure is omitted from the plan view of FIG. 18, to provide an unobstructed view of the source and body regions 106, 802 of the radial power transistor.

In FIGS. 18 and 19, a first (outer) field plate structure 108_1 laterally surrounds the radial power transistor. Additional field plate structures 108_2 extend from the frontside 110 of the silicon layer 102 through the bulk region 800 and through the semiconductor layer 100 of the radial power transistor. For example, the field plate structures 108_2 may extend from the frontside 110 of the silicon layer 102 through at least 70% or at least 90% of the thickness of the semiconductor layer 100 or even through the complete semiconductor layer 100. The additional field plate structures 108_2 are needle-shaped and laterally spaced apart from one another.

In FIGS. 18 and 19, one or more additional polysilicon or metal field plates 808 overlay the frontside 110 of the silicon layer 100. The additional field plates 808 are not illustrated in the plan view of FIG. 18, to provide an unobstructed view of the additional field plate structures 108_2 in the bulk region 800. The field plate/semiconductor mesa 112, 304 of some or all of the additional field plate structures 1082 may be electrically connected to the overlying additional field plates 808 as shown in FIG. 19 and/or to doped regions (not shown in FIGS. 18 and 19) that have a higher doping concentration than a background doping concentration of the silicon layer 100. Electrically connecting the additional field plate structures 108_2 in this way extends the field plate potential into a depth of the silicon layer 100 to modulate the electric field inside the silicon layer 100, which enables changing the curvature of the electric field within the silicon layer and/or engineering the electric field to relieve stress on the drain region 104.

The additional field plate structures 108_2 may include short or extended trenches that extend in a radial or any other direction. The additional field plate structures 108_2 may have any arbitrary shape, e.g., U-shaped, striped, curved, rectilinear, circular, etc. The field plate/semiconductor mesa 112, 304 of the additional field plate structures 1082 may be electrically connected to different parts of the silicon layer 100 such as n/p-type contacts, to a field plate 808 above the silicon layer 100, to an adjacent field plate/mesa 112, 304, to a distant electric potential, e.g., fed from outside the device, to a field plate/mesa 112, 304 which is not adjacent, to an arbitrary point in the bulk region 800, etc. to direct a defined electric potential into a depth of the silicon layer 100.

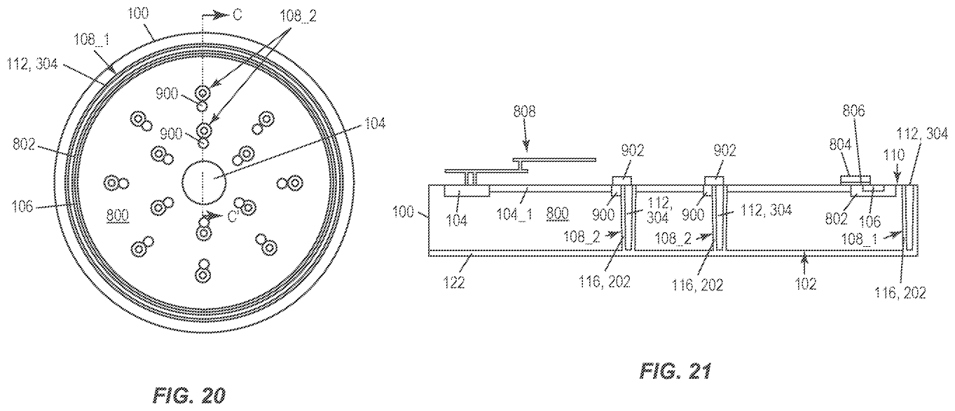

FIG. 20 illustrates a plan view of the frontside 110 of the silicon layer 100 and with the SOI device implemented as a radial power transistor, according to another embodiment. FIG. 21 illustrates a corresponding cross-sectional view along the line labelled C-C′ in FIG. 20. FIGS. 20 and 21 are similar to FIGS. 18 and 19. Differently, in FIGS. 20 and 21, the additional field plate structures 108_2 in the extension region 104_1 are electrically connected to doped regions 900 that have a higher doping concentration than a background doping concentration of the silicon layer 100. The electrical connection may be implemented by a polysilicon or metal layer 902. The field plate interconnecting layer 902 is not shown in the plan view of FIG. 20, to provide an unobstructed view of the additional field plate structures 108_2 and the doped regions 900 in the extension region 104_1 of the radial power transistor.

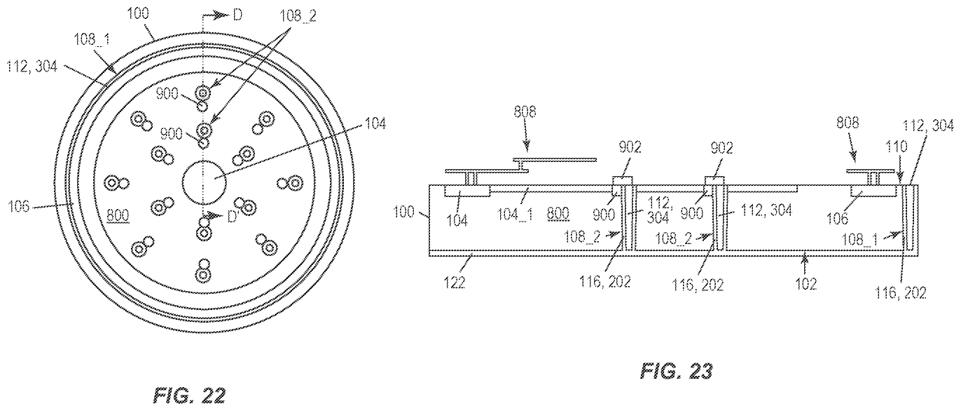

FIG. 22 illustrates a plan view of the frontside 110 of the silicon layer 100 and with the SOI device implemented as a radial power diode, according to an embodiment. FIG. 23 illustrates a corresponding cross-sectional view along the line labelled D-D′ in FIG. 22. Differently than the lateral power transistors shown in FIGS. 18 through 21, the high voltage region 104 of the SOI device is a cathode region of the radial power diode and the low voltage region 106 of the SOI device is the anode region of the radial power diode. The extension region 104_1 adjoining the high voltage region or cathode region 104 comprises the same doping type but with lower concentration as the high voltage region 104. The additional field plate structures 108_2 in the extension region 104_1 of the radial power diode may be electrically connected to doped regions 900 that have a higher doping concentration than a background doping concentration of the silicon layer 100 as shown in FIGS. 22 and 23, to one or more additional metal field plates 808 overlying the frontside 110 of the silicon layer 100 as shown in FIGS. 18 and 19, or some combination of both.

It should be emphasized that the additional field plates 808 shown in FIGS. 18 through 23 are optional.

Although the present disclosure is not so limited, the following numbered examples demonstrate one or more aspects of the disclosure.

Example 1. A semiconductor device, comprising: a silicon layer having an electrically insulated backside and a thickness in a range of 10 μm to 200 μm between a frontside of the silicon layer and the electrically insulated backside; a high voltage region and a low voltage region formed in the silicon layer and laterally spaced apart from one another; and a first field plate structure extending from the frontside into the silicon layer, the first field plate structure comprising a field plate laterally separated from the silicon layer by a dielectric material and/or a pn junction.

Example 2. The semiconductor device of example 1, wherein the first field plate structure adjoins the high voltage region, and wherein the field plate is electrically connected to a same potential as the high voltage region.

Example 3. The semiconductor device of example 1, wherein the first field plate structure adjoins the low voltage region, and wherein the field plate is electrically connected to a same potential as the low voltage region.

Example 4. The semiconductor device of any of examples 1 through 3, further comprising: a second field plate structure extending into the silicon layer from the frontside, the second field plate structure comprising a field plate laterally separated from the silicon layer by a dielectric material and/or a pn junction, wherein the first field plate structure adjoins the high voltage region and the field plate of the first field plate structure is electrically connected to a same potential as the high voltage region, wherein the second field plate structure adjoins the low voltage region and the field plate of the second field plate structure is electrically connected to a same potential as the low voltage region.

Example 5. The semiconductor device of any of examples 1 through 4, wherein the first field plate structure electrically isolates first and second circuit areas from one another within the silicon layer.

Example 6. The semiconductor device of example 5, wherein the field plate is electrically connected to a doped region of one of the first and second circuit areas.

Example 7. The semiconductor device of example 6, further comprising: a second field plate structure extending into the silicon layer from the frontside, the second field plate structure comprising a field plate laterally separated from the silicon layer by a dielectric material and/or a pn junction, wherein the second field plate structure electrically isolates the second circuit area from a third circuit area, wherein the field plate of the first field plate structure is electrically connected to a doped region of the first circuit area, wherein the field plate of the second field plate structure is electrically connected to a doped region of the second or the third circuit area.

Example 8. The semiconductor device of example 6, further comprising: a second field plate structure extending into the silicon layer from the frontside, the second field plate structure comprising a field plate laterally separated from the silicon layer by a dielectric material and/or a pn junction, wherein the second field plate structure electrically isolates the second circuit area from a third circuit area, wherein the field plate of the first field plate structure is electrically connected to a doped region of the second circuit area, and wherein the field plate of the second field plate structure is electrically connected to a doped region of the second circuit area.

Example 9. The semiconductor device of any of example 1, wherein the field plate is electrically connected to a doped region of the semiconductor layer, the doped region having a higher doping concentration than a background doping concentration of the silicon layer.

Example 10. The semiconductor device of example 9, wherein the doped region has a same conductivity type as the semiconductor layer.

Example 11. The semiconductor device of example 9, wherein the doped region has an opposite conductivity type as the semiconductor layer.

Example 12. The semiconductor device of example 1, wherein the field plate is electrically connected to an electric potential such that a depletion region, accumulation region, or conductive channel forms along a sidewall of the first field plate structure when the electric potential is applied.

Example 13. The semiconductor device of example 1, wherein the field plate is electrically floating.

Example 14. The semiconductor device of any of examples 1 through 13, wherein the high voltage region is a cathode region of a power diode, wherein the low voltage region is an anode region of the power diode, and wherein the first field plate structure extends through an n-type region of the power diode that extends from the cathode region in a direction of the anode region.

Example 15. The semiconductor device of any of examples 1 through 13, wherein the high voltage region is a drain region of a power transistor, wherein the low voltage region is a source region of the power transistor, and wherein the first field plate structure extends through an extension region or drift region of the power transistor that connects a body region of the power transistor to the drain region.

Example 16. The semiconductor device of example 14 or 15, wherein the first field plate structure comprises a needle-shaped trench that extends through the extension region or drift region.

Example 17. The semiconductor device of any of examples 14 through 16, wherein the field plate is electrically connected to an additional field plate overlaying the frontside of the silicon layer.

Example 18. The semiconductor device of any of examples 14 through 16, wherein the field plate is electrically connected to a doped region at the frontside of the silicon layer, and wherein the doped region has a higher doping concentration than a background doping concentration of the silicon layer.

Example 19. The semiconductor device of any of examples 14 through 18, further comprising: a plurality of additional field plate structures extending the frontside of the silicon layer through the extension region or drift region of the power transistor, each additional field plate structure comprising a field plate laterally separated from the silicon layer by a dielectric material and/or a pn junction, wherein the additional field plate structures are needle-shaped and laterally spaced apart from one another.

Example 20. The semiconductor device of any of examples 1 through 13, wherein the high voltage region is a drain region of a power transistor, wherein the low voltage region is a source region of the power transistor, wherein the first field plate structure extends at least partly along a body region interposed between the source region and the drain region, and wherein the field plate is biased such that an inversion region, accumulation region, or depletion region formed along a sidewall of the first field plate structure defines a side gate at least partly along the body region.

Example 21. The semiconductor device of example 20, wherein the first field plate structure laterally surrounds a device cell that includes the source region, the drain region, and the body region.

Example 22. The semiconductor device of example 21, further comprising: a second field plate structure extending from the frontside of the silicon layer into the body region, the second field plate structure comprising a field plate laterally separated from the silicon layer by a dielectric material and/or a pn junction, wherein the second field plate structure is spaced inward from the first field plate structure such that a segment of the body region is interposed between the first field plate structure and the second field plate structure, and wherein the field plate of the second field plate structure is biased such that an inversion region, accumulation region, or depletion region formed along a sidewall of the second field plate structure defines a side gate along a side of the body region segment opposite the first field plate structure.

Example 23. The semiconductor device of any of examples 1 through 22, wherein the first field plate structure encircles at least part of the silicon layer.

Example 24. The semiconductor device of any of examples 1 through 23, wherein the first field plate structure is segmented into a plurality of trench sections that are laterally spaced apart from one another by a region of the silicon layer.

Example 25. The semiconductor device of any of examples 1 through 24, wherein the first field plate structure terminates at a depth in the silicon layer before reaching the electrically insulated backside.

Example 26. The semiconductor device of any of examples 1 through 25, wherein the field plate comprises a mesa of the silicon layer that is surrounded by the dielectric material and/or pn junction.

Example 27. The semiconductor device of any of examples 1 through 25, wherein the field plate comprises polysilicon surrounded by the dielectric material and/or pn junction of the first field plate structure.

Example 28. The semiconductor device of any of examples 1 through 27, wherein the first field plate structure comprises a trench that extends from the frontside into the silicon layer, and wherein the dielectric material lines a sidewall and a bottom of the trench.

Example 29. The semiconductor device of any of examples 1 through 27, wherein the first field plate structure comprises first and second trenches that each extend from the frontside into the silicon layer and delimit a semiconductor mesa, wherein the first and second trenches are filled with the dielectric material, and wherein the semiconductor mesa delimited by the first and second trenches forms the field plate.

Example 30. The semiconductor device of any of examples 1 through 27, wherein the first field plate structure comprises a trench that extends from the frontside into the silicon layer and terminates at the electrically insulated backside, wherein the dielectric material lines a sidewall of the trench, and wherein the field plate terminates at the electrically insulated backside at a bottom of the trench.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to mean all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a silicon layer having an electrically insulated backside and a thickness in a range of 10 μm to 200 μm between a frontside of the silicon layer and the electrically insulated backside;
a high voltage region and a low voltage region formed in the silicon layer and laterally spaced apart from one another; and
a first field plate structure extending from the frontside into the silicon layer, the first field plate structure comprising a field plate laterally separated from the silicon layer by a dielectric material and/or a pn junction.

2. The semiconductor device of claim 1, wherein the first field plate structure adjoins the high voltage region, and wherein the field plate is electrically connected to a same potential as the high voltage region.

3. The semiconductor device of claim 1, wherein the first field plate structure adjoins the low voltage region, and wherein the field plate is electrically connected to a same potential as the low voltage region.

4. The semiconductor device of claim 1, further comprising:
a second field plate structure extending into the silicon layer from the frontside, the second field plate structure comprising a field plate laterally separated from the silicon layer by a dielectric material and/or a pn junction,
wherein the first field plate structure adjoins the high voltage region and the field plate of the first field plate structure is electrically connected to a same potential as the high voltage region,
wherein the second field plate structure adjoins the low voltage region and the field plate of the second field plate structure is electrically connected to a same potential as the low voltage region.

5. The semiconductor device of claim 1, wherein the first field plate structure electrically isolates first and second circuit areas from one another within the silicon layer.

6. The semiconductor device of claim 5, wherein the field plate is electrically connected to a doped region of one of the first and second circuit areas.

7. The semiconductor device of claim 6, further comprising:
a second field plate structure extending into the silicon layer from the frontside, the second field plate structure comprising a field plate laterally separated from the silicon layer by a dielectric material and/or a pn junction,
wherein the second field plate structure electrically isolates the second circuit area from a third circuit area,
wherein the field plate of the first field plate structure is electrically connected to a doped region of the first circuit area,
wherein the field plate of the second field plate structure is electrically connected to a doped region of the second or the third circuit area.

8. The semiconductor device of claim 6, further comprising:
a second field plate structure extending into the silicon layer from the frontside, the second field plate structure comprising a field plate laterally separated from the silicon layer by a dielectric material and/or a pn junction,
wherein the second field plate structure electrically isolates the second circuit area from a third circuit area,
wherein the field plate of the first field plate structure is electrically connected to a doped region of the second circuit area,
wherein the field plate of the second field plate structure is electrically connected to a doped region of the second circuit area.

9. The semiconductor device of claim 1, wherein the field plate is electrically connected to a doped region of the semiconductor layer, the doped region having a higher doping concentration than a background doping concentration of the silicon layer.

10. The semiconductor device of claim 9, wherein the doped region has a same conductivity type as the semiconductor layer.

11. The semiconductor device of claim 9, wherein the doped region has an opposite conductivity type as the semiconductor layer.

12. The semiconductor device of claim 1, wherein the field plate is electrically connected to an electric potential such that a depletion region, accumulation region, or conductive channel forms along a sidewall of the first field plate structure when the electric potential is applied.

13. The semiconductor device of claim 1, wherein the field plate is electrically floating.

14. The semiconductor device of claim 1, wherein the high voltage region is a cathode region of a power diode, wherein the low voltage region is an anode region of the power diode, and wherein the first field plate structure extends through an n-type region of the power diode that extends from the cathode region in a direction of the anode region.

15. The semiconductor device of claim 1, wherein the high voltage region is a drain region of a power transistor, wherein the low voltage region is a source region of the power transistor, and wherein the first field plate structure extends through an extension region of the power transistor that connects a body region of the power transistor to the drain region.

16. The semiconductor device of claim 15, wherein the first field plate structure comprises a needle-shaped trench that extends through the extension region.

17. The semiconductor device of claim 15, wherein the field plate is electrically connected to an additional field plate overlaying the frontside of the silicon layer.

18. The semiconductor device of claim 15, wherein the field plate is electrically connected to a doped region at the frontside of the silicon layer, and wherein the doped region has a higher doping concentration than a background doping concentration of the silicon layer.

19. The semiconductor device of claim 15, further comprising:
a plurality of additional field plate structures extending the frontside of the silicon layer through the extension region of the power transistor, each additional field plate structure comprising a field plate laterally separated from the silicon layer by a dielectric material and/or a pn junction,
wherein the additional field plate structures are needle-shaped and laterally spaced apart from one another.

20. The semiconductor device of claim 1, wherein the high voltage region is a drain region of a power transistor, wherein the low voltage region is a source region of the power transistor, wherein the first field plate structure extends at least partly along a body region interposed between the source region and the drain region, and wherein the field plate is biased such that an inversion region, accumulation region, or depletion region formed along a sidewall of the first field plate structure defines a side gate at least partly along the body region.

21. The semiconductor device of claim 20, wherein the first field plate structure laterally surrounds a device cell that includes the source region, the drain region, and the body region.

22. The semiconductor device of claim 21, further comprising:
a second field plate structure extending from the frontside of the silicon layer into the body region, the second field plate structure comprising a field plate laterally separated from the silicon layer by a dielectric material and/or a pn junction,
wherein the second field plate structure is spaced inward from the first field plate structure such that a segment of the body region is interposed between the first field plate structure and the second field plate structure, and
wherein the field plate of the second field plate structure is biased such that an inversion region, accumulation region, or depletion region formed along a sidewall of the second field plate structure defines a side gate along a side of the body region segment opposite the first field plate structure.

23. The semiconductor device of claim 1, wherein the first field plate structure encircles at least part of the silicon layer.

24. The semiconductor device of claim 1, wherein the first field plate structure is segmented into a plurality of trench sections that are laterally spaced apart from one another by a region of the silicon layer.

25. The semiconductor device of claim 1, wherein the first field plate structure terminates at a depth in the silicon layer before reaching the electrically insulated backside.

26. The semiconductor device of claim 1, wherein the field plate comprises a mesa of the silicon layer that is surrounded by the dielectric material and/or pn junction.

27. The semiconductor device of claim 1, wherein the field plate comprises polysilicon surrounded by the dielectric material and/or pn junction of the first field plate structure.

28. The semiconductor device of claim 1, wherein the first field plate structure comprises a trench that extends from the frontside into the silicon layer, and wherein the dielectric material lines a sidewall and a bottom of the trench.

29. The semiconductor device of claim 1, wherein the first field plate structure comprises first and second trenches that each extend from the frontside into the silicon layer and delimit a semiconductor mesa, wherein the first and second trenches are filled with the dielectric material, and wherein the semiconductor mesa delimited by the first and second trenches forms the field plate.

30. The semiconductor device of claim 1, wherein the first field plate structure comprises a trench that extends from the frontside into the silicon layer and terminates at the electrically insulated backside, wherein the dielectric material lines a sidewall of the trench, and wherein the field plate terminates at the electrically insulated backside at a bottom of the trench.
